(19) United States
(12) Patent Application Publication
(10) Pub. No.: US 2017/0257965 A1
(43) Pub. Date: Sep. 7, 2017

(54) ELECTRONIC DEVICE WITH SUPPORT APPARATUS

(71) Applicants: HONGFUJIN PRECISION ELECTRONICS(CHONGQING)CO. LTD, Chongqing (CN); HON HAI PRECISION INDUSTRY CO., LTD., New Taipei (CN)

(72) Inventors: RI-DONG HUANG, Shenzhen (CN); ZHAO-YU WANG, Shenzhen (CN); TE-HSU WANG, New Taipei (TW)

(21) Appl. No.: 15/075,837

(22) Filed: Mar. 21, 2016

(30) Foreign Application Priority Data
Mar. 1, 2016 (CN) 201620154381.3

(51) Int. Cl. H05K 7/14

(52) U.S. Cl. CPC H05K 7/14

(57) ABSTRACT

A supported electronic device includes a display, at least one mounting apparatus mounted to the display, and a first support member rotatably mounted to the mounting apparatus. The first support member includes a first support frame, a mounting member, a rotating member, and two fastening members fastening the mounting member to the first support frame. The rotating member includes a rotating shaft and a locking member. One end of the rotating shaft is rotatably mounted to the mounting apparatus, and other end of the rotating shaft passes through the mounting member and is fastened to the fastening member and is locked in the first support frame.

### FIELD

The subject matter herein generally relates to a support apparatus and an electronic device with the support apparatus.

### BACKGROUND

A display can be supported by a support frame. When the display needs to be adjusted for viewing, the display is rotated and the display is supported by the support frame.

### BRIEF DESCRIPTION OF THE DRAWINGS

Implementations of the present technology will now be described, by way of example only, with reference to the attached figures.

FIG. 1 is an assembled, isometric view of an exemplary embodiment of an electronic device, which comprises a first support member.

FIG. 2 is an exploded, isometric view of the electronic device of FIG. 1.

FIG. 3 is an exploded, isometric view of the first support member of FIG. 1.

FIG. 4 is an isometric view of the electronic device of FIG. 2, but viewed from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “inside” indicates that at least a portion of a region is partially contained within a boundary formed by the object. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

The present disclosure relates to a support apparatus and an electronic device with the support apparatus.

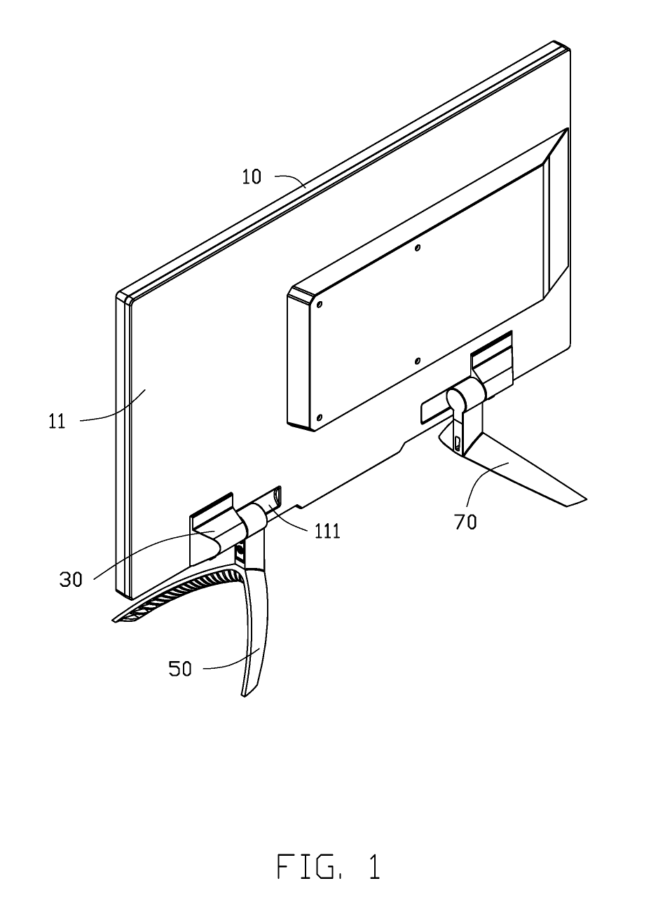

FIG. 1 illustrates an electronic device. The electronic device comprises a display 10, two mounting apparatus 30, a first support member 50, and a second support member 70.

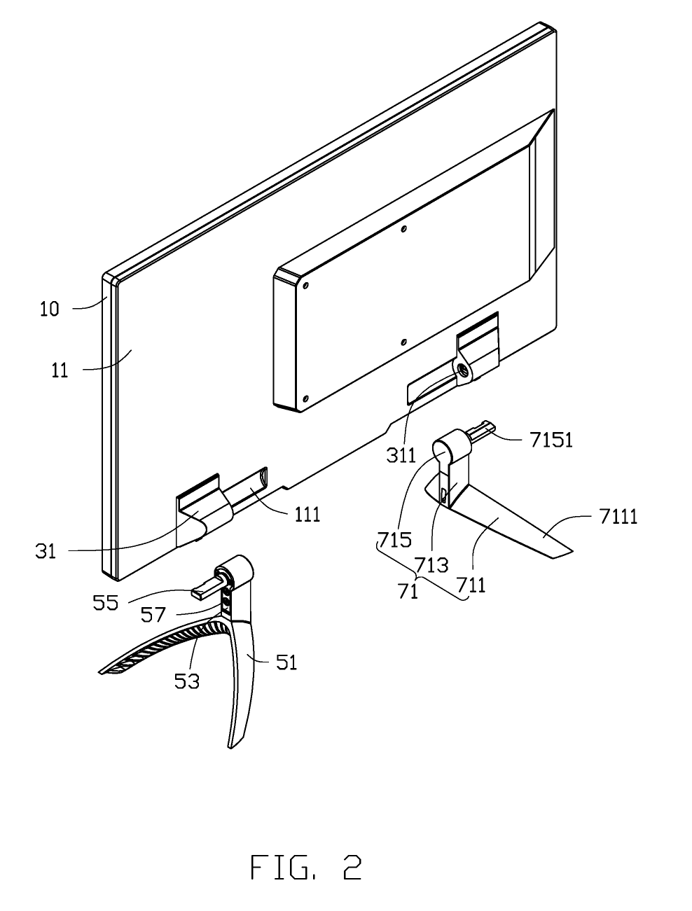

Referring to FIG. 2, the display 10 comprises a cover 11, and the two mounting apparatus 30 are mounted on the cover 11. The cover 11 defines two dents 111 beside the mounting apparatus 30.

Each mounting apparatus 30 comprises a mounting knob 31 mounted on the cover 11. Each mounting knob 31 defines a mounting hole 311.

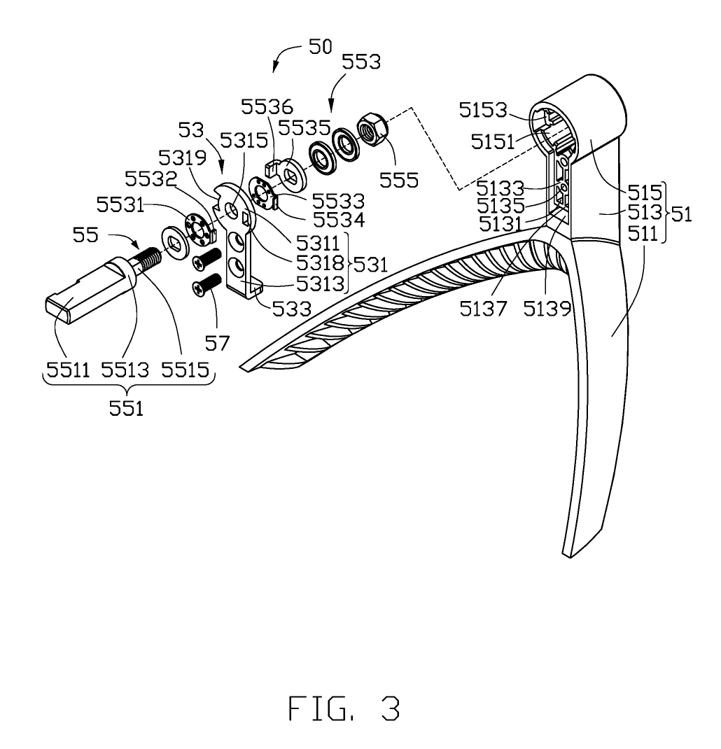

FIG. 3 illustrates the first support member 50. The first support member 50 comprises a first support frame 51, a mounting member 53, a rotating member 55, and two fastening members 57. The first support frame 51 comprises a first support portion 511, a first connecting portion 513 coupled to a top end of the first support portion 511, and a first rotating portion 515 coupled to the first connecting portion 513. The first support portion 511 comprises two holders 5111, and an acute angle is defined the two holders 5111. A side of the first connecting portion 513 defines a first receiving groove 5131, and two pillars 5133 spaced from each other are coupled to a bottom side of the first receiving groove 5131. Each pillar 5133 defines a screw hole 5135. A connecting plate 5137 is coupled to two sides of the first receiving groove 5131. The connecting plate 5137 and the first receiving groove 5131 cooperatively define a receiving space 5139. In at least one embodiment, the first rotating portion 515 is substantially cylindrical. The first rotating portion 515 defines a second receiving groove 5151 coupled to the first receiving groove 5131 and in axial alignment. A plurality of raised knobs 5153 are coupled to an inside of the second receiving groove 5151, each raised knob 5153 being spaced from each other.

The mounting member 53 comprises a connecting piece 531 and a stop piece 533 vertically coupled to the connecting piece 531. The connecting piece 531 comprises a locking piece 5311 and a mounting piece 5313 coupled to the locking piece 5311. In at least one embodiment, the locking piece 5311 is circular. The locking piece 5311 defines a through hole 5315. The mounting piece 5313 defines two through holes 5317 spaced from each other. The locking piece 5311 defines a locking hole 5318 beside one side of the through hole 5315, and defines a locking opening 5319 beside other side of the through hole 5315.

The rotating member 55 comprises a rotating shaft 551, a plurality of spacers 553, and a locking member 555. The rotating shaft 551 comprises a rotating post 5511 rotatably mounted in the mounting hole 311 of the mounting knob 31, a raised platform 5513 coupled to the rotating post 5511, and a fastening portion 5515 extending from a middle portion of the raised platform 5513. In at least one embodiment, the fastening portion 5515 can be a screw. The spacers 553 comprise a first spacer 5531, a second spacer 5533, and a third spacer 5535. A first hook 5532 is coupled to the first spacer 5531, opposite to the locking hole 5318. A second hook 5534 is coupled to the second spacer 5533, opposite to the locking hole 5318. A third hook 5536 is coupled to the third spacer 5535, opposite to the locking opening 5319. In at least one embodiment, the locking member 555 is a nut.

In at least one embodiment, the two fastening members 57 are screws.

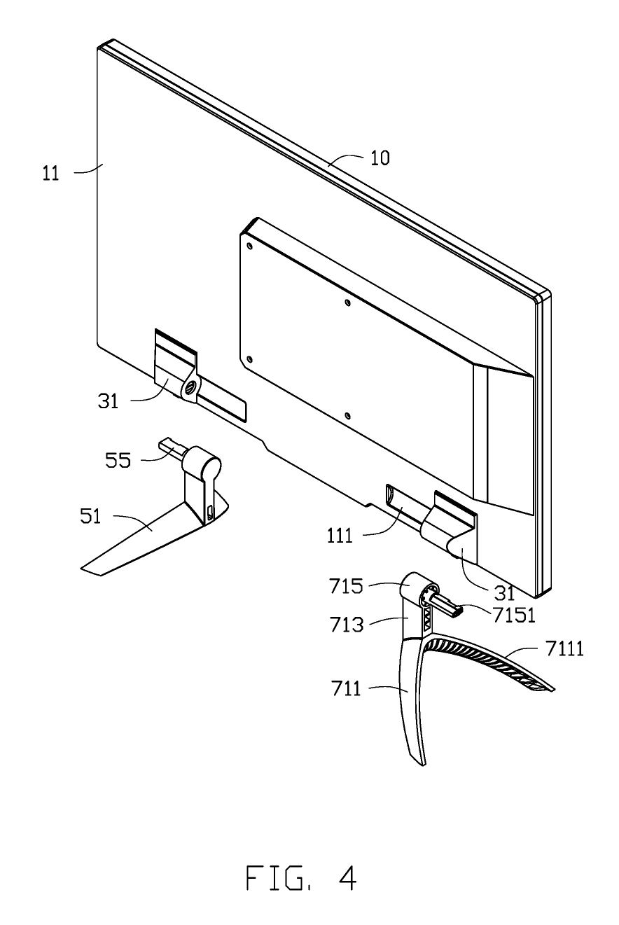

Referring to FIG. 4, the second support member 70 comprises a second support frame 71. The second support frame 71 comprises a second support portion 711, a second connecting portion 713 coupled to a top end of the second support portion 711, and a second rotating portion 715 coupled to the second connecting portion 713. The second support portion 715 comprises two holders 7111, the two holders 7111 forming an acute angle. A rotating shaft 7151 is fixed to the second rotating portion 715, the rotating shaft 7151 being mounted in the mounting hole 311 of the mounting knob 31.

Referring to FIG. 1, in assembly of the first support member 50, the fastening portion 5515 of the rotating shaft 551 passes through the first spacer 5531, the through hole 5315 of the mounting member 53, and the second and third spacers 5533 and 5535, and is fastened in the locking member 555. The first spacer 5531 is stopped at the raised platform 5513 of the rotating shaft 551. The first hook 5532 of the first spacer 5531 and the second hook 5534 of the second spacer 5533 are locked in the locking hole 5138 of the locking piece 5311. The third hook 5536 of the third spacer 5535 is locked in the locking opening 5139 of the locking piece 5311. The fastening portion 5515 of the rotating shaft 551 is opposite to the second receiving groove 5151 of the first support frame 51. The locking piece 5311 is opposite to the second receiving groove 5151 of the first rotating portion 515 and the two through holes 5317 of the mounting piece 5313 are opposite to the two screw holes 5135 of the pillars 5133. The stop piece 533 is opposite to the receiving space 5139. The rotating shaft 551 is moved to the second receiving groove 5151 until the locking piece 5311 of the mounting member 53 is stopped at the first rotating portion 515. The mounting piece 5313 of the mounting member 53 is stopped at the connecting plate 5137. The locking member 555 is locked between the raised knobs 5153 of the second receiving groove 5151. The stop piece 533 of the mounting member 53 is received in the receiving space 5139 and the mounting piece 5313 is stopped at the connecting plate 5137. The two fastening members 57 pass through the two through holes 5317 of the mounting piece 5313 and are fastened in the screw holes 5135 of the pillars 5133.

In assembly of the electronic device, the rotating post 5511 of the first support member 50 is rotatably mounted in the mounting hole 311 of the mounting apparatus 30. The first rotating portion 515 of the first support frame 51 is received in the dent 111 of the cover 11. The first support member 50 is mounted to the display 10. The rotating shaft 7151 of the second support frame 71 is rotatably mounted in the mounting hole 311 of the mounting apparatus 30. The second rotating portion 715 of the second support frame 71 is received in the dent 111 of the cover 11. The electronic device is thereby assembled.

When the viewing angle of the display 10 needs to be adjusted, the display 10 is rotated, and the rotating portion 5511 of the first support member 50 and the rotating shaft 7151 of the second support frame 71 are rotated with the display 10. The rotating shaft 551 of the first frame 50 is abutted by the plurality of spacers 553 and the display 10 is thus fixed.

The first support member 50 is rotatably mounted to the display 10, and the first support frame 51 is firm fastened to the rotating member 55 by the mounting member 53 and the fastening members 57.

The embodiments shown and described above are only examples. Even though numerous characteristics and advantages of the present technology have been set forth in the foregoing description, together with details of the structure and function of the present disclosure, the disclosure is illustrative only, and changes may be made in the details, including matters of shape, size, and arrangement of the parts within the principles of the present disclosure, up to and including the full extent established by the broad general meaning of the terms used in the claims.

What is claimed is:

1. An electronic device comprising:
a display;
at least one mounting apparatus mounted to the display; and
a first support member rotatably mounted to the mounting apparatus, the first support member comprising:
a first support frame;
a mounting member;
a rotating member comprising a rotating shaft and a locking member, wherein a first end of the rotating shaft is rotatably mounted to the at least one mounting apparatus, and a second end opposite the first end of the rotating shaft passes through the mounting member and is fastened to the fastening member to be locked in the first support frame; and
two fastening members fastening the mounting member to the first support frame.

2. The electronic device of claim 1, wherein the first support frame comprise a first support portion, a first connecting portion coupled to the first support portion and a first rotating portion coupled to the first connecting portion, the first support portion comprises two holders, the mounting member is locked on the first connecting portion by the two fastening members, and the rotating shaft is locked to the first rotating portion.

3. The electronic device of claim 2, wherein the mounting member comprises a connecting piece and a stop piece coupled to the connecting piece, the connecting piece comprises a locking piece and a mounting piece coupled to the locking piece, the mounting piece defines two through holes, the first connecting portion defines a first receiving groove, two pillars are coupled to a bottom side of the first receiving groove, each pillar defines a screw hole, the two fastening members pass through the through holes of the mounting piece and are fastened in the screw holes of the pillars, and the mounting piece is stopped at the first connecting portion.

4. The electronic device of claim 3, wherein a connecting plate is coupled to two side of the first receiving groove, the connecting plate and the first receiving groove cooperatively define a receiving space, the stop piece of the mounting member is received in the receiving space, and the mounting piece is stopped at the connecting plate.

5. The electronic device of claim 3, wherein the first rotating portion defines a second receiving groove, a plurality of raised knobs are coupled to an inside of the second receiving groove and spaced from each other, and the fastening members fastened in the rotating shaft is locked between the raised knobs of the second receiving groove.

6. The electronic device of claim 3, wherein the rotating shaft comprises a rotating post rotatably mounted in the mounting apparatus, a raised platform coupled to the rotating post and a fastening portion extending from a middle portion of the raised platform, the fastening portion passes through the locking piece and is fastened into the fastening member.

7. The electronic device of claim 6, wherein the rotating member comprises a first spacer, a second spacer and a third spacer, the fastening portion passes through the first spacer, the second spacer and the third spacer to be fastened in the fastening member.

8. The electronic device of claim 7, wherein the locking piece defines a locking hole and a locking opening, a first hook is coupled to the first spacer and is locked in the locking hole, a second hook is coupled to the second spacer and is locked in the locking hole, and a third hook is coupled to the third spacer and is locked in the locking opening.

9. The electronic device of claim 6, wherein the display comprises a cover, the mounting apparatus comprises two mounting knobs mounted to the cover, and each mounting knob defines a mounting hole to be coupled to the rotating portion of the rotating shaft.

10. The electronic device of claim 9, wherein the electronic device comprises a second support member, the second support member comprises a second support frame, the second support frame comprises a second support portion, a second connecting portion coupled to a top end of the second support portion and a second rotating portion coupled to the second connecting portion, a rotating shaft is fixed to the second rotating portion, and is mounted in the mounting hole of the mounting knob.

11. A support apparatus to support a display, the support apparatus comprising:
at least one mounting apparatus mounted to the display; and
a first support member rotatably mounted to the mounting apparatus, the first support member comprising:
a first support frame;
a mounting member;
a rotating member comprising a rotating shaft and a locking member, wherein a first end of the rotating shaft is rotatably mounted to the at least one mounting apparatus, and a second end opposite the first end of the rotating shaft passes through the mounting member and is fastened to the fastening member to be locked in the first support frame; and
two fastening members fastening the mounting member to the first support frame.

12. The support apparatus of claim 11, wherein the first support frame comprise a first support portion, a first connecting portion coupled to the first support portion and a first rotating portion coupled to the first connecting portion, the first support portion comprises two holders, the mounting member is locked on the first connecting portion by the two fastening members, and the rotating shaft is locked to the first rotating portion.

13. The support apparatus of claim 12, wherein the mounting member comprises a connecting piece and a stop piece coupled to the connecting piece, the connecting piece comprises a locking piece and a mounting piece coupled to the locking piece, the mounting piece defines two through holes, the first connecting portion defines a first receiving groove, two pillars are coupled to a bottom side of the first receiving groove, each pillar defines a screw hole, the two fastening members pass through the through holes of the mounting piece and are fastened in the screw holes of the pillars, and the mounting piece is stopped at the first connecting portion.

14. The support apparatus of claim 13, wherein a connecting plate is coupled to two side of the first receiving groove, the connecting plate and the first receiving groove cooperatively define a receiving space, the stop piece of the mounting member is received in the receiving space, and the mounting piece is stopped at the connecting plate.

15. The support apparatus of claim 13, wherein the first rotating portion defines a second receiving groove, a plurality of raised knobs are coupled to an inside of the second receiving groove and spaced from each other, and the fastening members fastened in the rotating shaft is locked between the raised knobs of the second receiving groove.

16. The support apparatus of claim 13, wherein the rotating shaft comprises a rotating post rotatably mounted in the mounting apparatus, a raised platform coupled to the rotating post and a fastening portion extending from a middle portion of the raised platform, the fastening portion passes through the locking piece and is fastened into the fastening member.

17. The support apparatus of claim 16, wherein the rotating member comprises a first spacer, a second spacer and a third spacer, the fastening portion passes through the first spacer, the second spacer and the third spacer to be fastened in the fastening member.

18. The support apparatus of claim 17, wherein the locking piece defines a locking hole and a locking opening, a first hook is coupled to the first spacer and is locked in the locking hole, a second hook is coupled to the second spacer and is locked in the locking hole, and a third hook is coupled to the third spacer and is locked in the locking opening.

19. The support apparatus of claim 16, wherein the display comprises a cover, the mounting apparatus comprises two mounting knobs mounted to the cover, and each mounting knob defines a mounting hole to be coupled to the rotating portion of the rotating shaft.

20. The support apparatus of claim 19, wherein the electronic device comprises a second support member, the second support member comprises a second support frame, the second support frame comprises a second support portion, a second connecting portion coupled to a top end of the second support portion and a second rotating portion coupled to the second connecting portion, a rotating shaft is fixed to the second rotating portion, and is mounted in the mounting hole of the mounting knob.
